(19) United States
(12) Patent Application Publication
(10) Pub. No.: US 2023/0263063 A1
(43) Pub. Date: Aug. 17, 2023

(54) TRANSDUCER AND THERMOELECTRIC TRANSFER RESISTOR

(71) Applicant: Miguel Angel DELLA FERA, Salerno (IT)

(72) Inventor: Miguel Angel DELLA FERA, Salerno (IT)

(21) Appl. No.: 18/025,894

(22) PCT Filed: Oct. 30, 2020
(86) PCT No.: PCT/IT2020/000073

§ 371 Date: Mar. 11, 2023

(51) Int. Cl. H10N 10/854; H10N 10/17

(52) U.S. Cl. CPC H10N 10/854; H10N 10/17

(57) ABSTRACT

The device presented in this patent application is a solid state “thermoelectric device”, which receives energy from an external heat source by direct contact or by radiation (input), and uses part of that thermal energy to generate electrical energy by radiation (output). This can be used to compose a thermoelectric generator, and/or as a “thermo electronic regulator” in an electronic circuit. Transducers with the same structure and that operate in a similar way, that is, they receive energy from an external source of electromagnetic radiation, or by direct contact with a heat source and transform it by radiation into electrical energy, they are the elements that make up the photovoltaic cells (photoelectric effect) and thermionic generators (thermionic effect). On the other hand, electronic devices that regulate the flow of current in a certain circuit such as transistors and some type of diode in particular, are composed of materials that interact with each other in a similar way to those used by this thermoelectric device, but are generally powered by electrical energy.

The design and materials that make up the structure of this device are exactly the same, whether it is used as a thermoelectric transducer or as a thermo electronic regulator, the only variation between both functions will be the thickness of one of its components; so that we will describe its operation both for one mode of use and for the other.

We begin with the function of a transducer as an element of a thermoelectric generator. A TRANSDUCER is a device with the ability to receive input, some energy of an electrical, mechanical, acoustic nature, etc., and supply output, another energy of a different nature but whose characteristics depend on the energy received.

The term THERMOELECTRIC, specifies the relationship between thermal and electrical energies making them dependent on each other, and it refers interchangeably to any of the “PHYSICAL EFFECTS” that makes the two forms of energy interact, (for example, Seebeck, Peltier, Thomson, Joule, Edison, etc.).

The other term, TRANSFER RESISTOR, and its contraction TRANSISTOR. It refers to a device with three basic functions that suggest electronic control in the variation of resistance in a circuit:

CUT, which would be the equivalent of a resistance so high that it prevents the flow of current through the circuit; SATURATION, otherwise, a resistance so low that it allows the free flow of current through the circuit; and ACTIVE, makes the transistor perform specifically as an amplifier.

We must then consider the thermal energy as the (input) energy of this transducer, whose origin is the heat from an external source.

Heat is transmitted from one place to another in three different ways:
By conduction between solid bodies
By convection in fluids (liquids or gases), and
By radiation through the medium in which the radiation can spread.

This is a solid state device, so regardless of whether it is in direct contact with the heat source, or whether the heat receives it by radiation from the source, the way it (heat) spreads throughout its structure is by “conduction”; we must also consider that the device is made up of several different elements, and that each one of them has its own “thermal characteristics”, the main ones are:
Thermal conductivity (λ).
Density (ρ).
Specific volumetric heat (ρCp).
Thermal diffusivity (a), and
Thermal effusiveness (b).

But for the purposes of this work, we will only take into account the “THERMAL CONDUCTIVITY (λ)” of the metals that, according to a selection that will be explained later, could make up the proposed device, and that including their respective coefficients of thermal conductivity (λ=W/Km) (watts/Kelvin×meters) are the following:

TABLE 1

| | | |
|---|---|---|
| Nickel (Ni) 90.7 W/K · m | Chromium(Cr) 93.7 W/K · m | Iron (Fe) 80.2 W/K · m |
| Titanium (Ti) 21.9 W/K · m | Tungsten (W) 174 W/K · m | Cobalt (Co) 100 W/K · m |
| Rhodium (Rh) 150 W/K · m | Iridium (Ir) 147 W/K · m | Platinum (Pt) 71.6 W/K · m |
| Ruthenium (Ru) 150 W/K · m | Manganese (Mn) 7.82 W/K · m | Rhenium (Re) 47.9 W/K · m |
| Molybdenum (Mo) 139 W/K · m | Zirconium (Zr) 22.7 W/K · m | Hafnium (Hf) 23 W/K · m |
| Scandium (Sc) 15.8 W/K · m | Yttrium (Y) 17.2 W/K · m | Tantalum (Ta) 57.5 W/K · m |
| Copper (Cu) 400 W/K · m | Silver (Ag) 429 W/K · m | Gold (Au) 317 W/K · m |

Conduction and convection always occur within matter, when it has already received the heat from the source, but radiation has some characteristics that are explained by its own definition.

Thermal or calorific radiation is: The emission and propagation outwards of the thermal energy of any physical system whose temperature is greater than absolute zero (0° K.=−273.15° C.), transformed into electromagnetic waves.

But this is only one form of radiation; and the common factor is that all forms of radiation propagate energy, either in the form of electromagnetic waves such as heat, UV rays, radio and TV waves, etc., or as subatomic particles, which in turn can have mass like neutrons, protons, electrons, or ions, or they can be massless energy particles (having relativistic mass) called photons; and all these forms of energy interact in some way with matter.

The interaction “Matter-Radiation” must be considered from two points of view:
The absorption of radiation; the one received by matter (for example, a transducer of any type) from an external source, and
The emission of radiation; the one emitted by matter (by the same transducer) after being exited.

In general, all the transducers that make up commercial devices that transform the heat energy they receive from an external source, either by some type of radiation or by direct contact with the source, and convert it into electrical energy by radiation (which is generally radiation from subatomic particles), take the matter electrons to a higher energy level, and the energy necessary for this to happen with most distant electrons from the nucleus of the atom of the matter, is defined as the “WORKING FUNCTION” of the materials that compose it.

The physics of the solid state defines the WORKING FUNCTION or EXTRACTION WORK, as the minimum energy necessary (normally measured in electron volts), to start an electron from a solid, to a point immediately outside the surface of the solid (or the energy required to move an electron from the “Fermi energy level” which is the highest level occupied by a quantum system at a temperature of 0° K., to a vacuum). Here the term “immediately out” means that the final position of the electron is far from the surface on an atomic scale but still close to the solid on a macroscopic scale”.

The most common commercial devices of this type are: photoelectric and/or photovoltaic devices, and thermionic devices.

In the first case, the electrons of matter (the device) receive the excitation energy through the “photons” (radiation of subatomic particles) coming from an external source (visible or ultraviolet light), the incidence of these on the structure of matter (absorption of radiation) released from its surface charge-carrying electrons with a kinetic energy greater than zero (emission of radiation from subatomic particles).

The process occurs only in the case that the solid matter (the device) receives enough energy from the photons, which depends exclusively on the minimum frequency (radiation threshold) below which the electrons will not be released (Photoelectrons), this process is called photoelectric work.

The level of energy required for this work is specific to each material and in solid state physics it is called PHOTOELECTRIC WORK FUNCTION.

In the second case, the electrons gain their energy from heat, instead of doing it through photons, the solid material (the device) increases its temperature (absorption of electromagnetic radiation) to the point of causing them to detach from its surface electrons (emission of radiation from subatomic particles), with enough kinetic energy to leave the solid matter (the cathode of the device), crossing a vacuum created intentionally for that purpose, to reach another point with opposite polarity (the anode of the device).

In this process, a large number of different frequencies and wavelengths components of the electromagnetic radiation spectrum are received together, but this does not represent any inconvenience for the emission of electrons (Thermo electrons) because it only depends on the absolute temperature of the system (average temperature with respect to 0° K.), and based on this it is called thermionic work.

As for photoelectric work, each material requires a specific amount of energy to carry out the thermionic work, which in this case the solid state physics defines as the THERMIONIC WORK FUNCTION.

(The terms Photoelectrons and Thermo electrons always refer to the same electrons, and were only used as a distinction).

For the same material, the photoelectric work (if it is a photo emitter), is always less than the thermionic work.

In a very superficial way this is explained as follows:

In photoelectric work, the excitation energy is received from a flow of energetic particles without mass (with relativistic mass) PHOTONS, with a certain wavelength and a specific frequency for that material, below of which no emission of electrons will occur. As they do not have mass there is no collision between particles, in this way the electrons of the matter receive without any loss all the energy that the PHOTONS carry with them, which also provides enough kinetic energy to separate them from the solid.

On the other hand, for thermionic work, the excitation energy comes from an external heat source, with electromagnetic waves of very varied lengths and frequencies, which progressively increase the temperature of the matter (it is transformed into thermal energy), part of this energy is lost by radiation and another part is used by the atoms of the matter to increase their kinetic energy; the collision between the mass particles absorbs another small part of that energy until the electrons accumulate enough kinetic energy to separate from the solid; this means that for the same material, the total energy required to pluck an electron is greater for thermionic work than for photoelectric work.

The output energy of the thermoelectric device that is being presented in this application is also a radiation of subatomic particles, specifically electrons, which will give rise to the electric current as mentioned before.

For the content of this document, the polarity of the anode is established according to the direction of the electric current, taking into account the universal definition of this phenomenon.

Consequently:

If a device consumes power, the anode is positive.

On the other hand, if it provides energy, the anode is negative.

The effects (photoelectric-photovoltaic) and thermionic have been pointed out, because in both cases radiation is transformed into electricity, and it becomes clear that although the final product is the same (specifically the extraction of electrons from a solid), the work Photoelectric and thermionic have different magnitudes even when it comes to the same material, because each one requires different amounts of energy.

The device presented in this document works, by making use of the difference between the magnitudes of the work functions of its components, exactly as photovoltaic and thermo ionic transducers do; however, although it feeds from a source of thermal energy such as thermionic devices, it processes that energy as a photovoltaic device does; that is, the electrons that are released from the cathode do not have to travel through an empty space before reaching the anode as in thermionic, but rather these (the electrons) immediately pass to the anode as in photovoltaic's. As the electrons are not given additional energy (kinetic energy), less total energy is used, that is, less heat, so the temperature at which it can start its operation is lower than the temperature required by a thermionic transducer.

The difference in the processing of energy between the transducers of the thermo ionic devices and this device is basically that, in the former the cathode and the anode are physically separated and intentionally polarized so that the electrons can make their way, whether in a vacuum or not, either by placing the device under the influence of a magnetic field or using any other mechanical means of conduction; while in the second case, that is, this device, the cathode and anode are in physical contact with a “junction” in which an ionic interaction is generated between the two components, which is specifically called a “non-ohmic” junction, and its differentiating effects can be seen in the development of this description.

In addition to the above effects, it is necessary to make a very brief review of other thermoelectric phenomena, which, although they have no direct relation with the radiation phenomenon, are part of the design of this device in order to improve its performance.

These are the widely known SEEBECK, PELTIER and THOMSON effects that in this case are taken into account for the “discharge or drain electrodes” that join the anode and cathode (the core) of this thermoelectric device with their connection terminals.

### RELATIONSHIP BETWEEN THE MENTIONED EFFECTS AND THE TRANSDUCERS

### Photoelectric-Photovoltaic Devices:

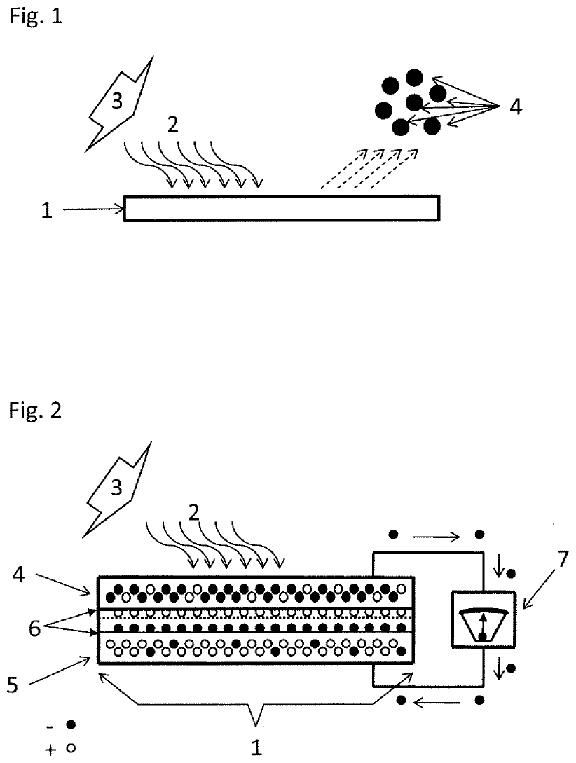

The photoelectric effect (FIG. 1), is the extraction of electrons (4) from a solid body (1) induced by the action of photons (2) from a visible or non-visible light source (3) as explained before, but in itself this effect does not generate an electric current that can be used.

The current is obtained (FIG. 2), by the same action of the photons (2), but when the solid body (1) is composed of an “N” type semiconductor material (4) in contact with another semiconductor but of the type “P” (5), forming what is known as “union NP”.

Right on this line of contact, the so-called “depletion region or potential barrier” is generated (6) that divides the device into two sections with opposite charges; and when the electrons that absorb the energy from the external source (3), instead of being expelled from the matter in the form of charged particles, are circulated from the area of matter with the highest concentration of charges negative “N” (4), up to the zone with the highest concentration of positive charges or holes “P” (5), closing the circuit with a charge “R” (7) that could be a current meter.

Such a depletion region or potential barrier is formed when:

At the contact line of the junction of two semiconductors “N” and “P”, the electrons of the material “N”, which are closer to the junction strip, are attracted by the positive charges or holes in the zone “P” Which are also closer to the union.

In this way the material “P” receives electrons that will become anions or negative ions; but at the same time they will have left empty spaces or holes in the material “N” that will be in opposition, the cations or positive ions of the set. That is why in (FIG. 2) the minus sign (−) in the “N” zone (4) is the most abundant and the plus sign (+) is the most abundant in the “P” zone (5) (these are the majority carriers in their respective areas). So in the depletion region (6) there will be cations (+c.i.) and anions (−a.i.) creating a positive potential on one side and a negative potential on the other, so between “N” and “P” there will be formed a potential difference (p.d.) or electric tension (but with a reverse polarity to the charges of the majority carriers).

This configuration of semiconductors in junction “N-P” is what is technically called in electronics a standard “diode”.

### Thermionics Divice:

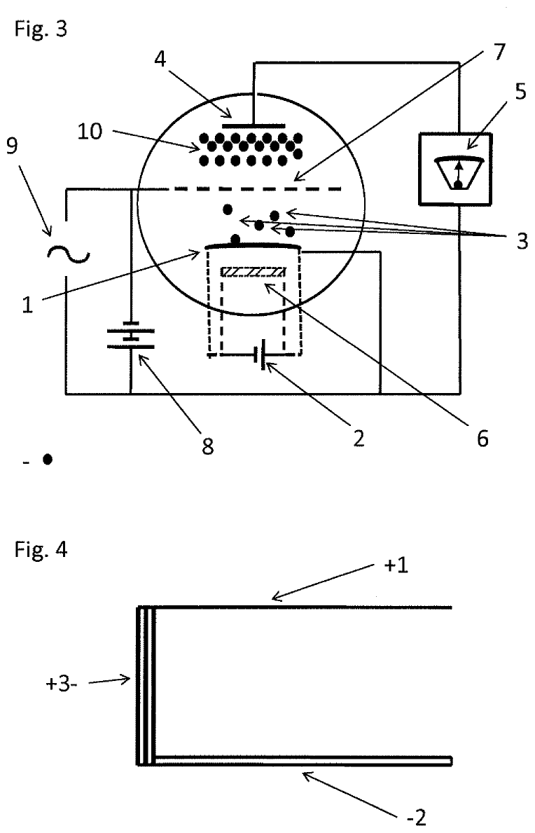

The principle of operation of a device of this nature is exactly the same, regardless of how the electrons have been emitted: by thermal radiation from an external source, by direct heat conduction, or by the Joule effect. But the simplest representation to describe the operation of a thermionic transducer is in the widely known vacuum valve, called thermionic valve or thermionic diode (FIG. 3) (it can also be seen in its more specialized version “the triode valve”).

Invented by John Ambrose Fleming around 1904, it is based on what was then known as the “Edison effect” and which is now called the “thermionic effect.” In it there is a displacement of electrons that come from an incandescent filament “cathode C” (1), fed by an electric current that raises its temperature (2). The electrons (3) released from the cathode are attracted by another opposed membrane with a positive charge “anode A” (4) crossing the “empty” space that separates them, which allows a suitable instrument for this purpose (“G” galvanometer) (5) record the passage of the current that is generated by the thermal radiation of electrons (3).

The cathode can be directly heated “direct Chaldean” (the same hot filament is the emitter) (1), or use a separate incandescent filament (6) to heat the electron emitting cathode (indirect heating). In either case, if the cathode is covered with a certain oxide, its function of work or work of extracting the electrons, is significantly reduced (sometimes up to almost half) for example, an uncovered direct heated tungsten filament has a work function between Φ=4.54 to 5.22 eV, but being covered by Thorium Oxide its work function is reduced to Φ=2.5 eV; which means that it requires less amount of excitation energy to function.

In these transducers, whether they are directly heated or indirectly heated, or that the cathode is made of a pure metal or covered by some oxide, it will always be from this “the cathode” (1) from where the electrons will be released (3), and the anode (4) will always be the point at which they will arrive crossing the void that separates them; the same happens in the triode valves, with the difference that in these a third regulating element is incorporated between the cathode and the anode, which is the control strip (7) and applying a small voltage (8) on it, which varies with the signal that must be modulated (9), the flow of electrons from the cathode to the anode can be made to be completely interrupted, and/or made higher or lower as required.

But the fact is that when the cathode is coated with an oxide, it ceases to be a “single material” and becomes a cathode composed of two solids, whether they are of the same gender or not, and an interaction between the two different work functions of the two materials will be inevitable.

Although the Work Functions are neither negative nor positive, there will be one of greater magnitude (which exerts more resistance to release its electrons) and another of less magnitude (which will allow its electrons to be released before the other material); Those are the electrons that the positively charged anode will attract to the other end of the device, regardless of which of the two materials it has already released.

In the operation of these devices, a process that increases against the conversion of energies occurs; at the beginning the electrons leaving the cathode do not meet any physical resistance on their way to the anode, because its elements are in a “vacuum” created with that intention, but as the flow of electrons reaches the anode they progressively accumulate around it, giving rise to an “electron cloud” (10) with the same negative charge of those who are arriving, their charges repel each other and progressively decreases the current flow to a much lower level than at the beginning.

It has been tried for a long time to avoid or reduce this inconvenience, incorporating in thermionic generators a series of mechanisms that, although they have a certain level of technical complexity, they promise to be viable in the very short term, but as reported by their own designers, they are still in the perfection phase.

For example:
The “THERMIONIC GENERATOR TO OBTAIN ELECTRICITY FROM HEAT AND SOLAR ENERGY”,
   developed at the Max Planck Institute for Solid State Research in Stuttgart, Germany.
The “PHOTON-ENHANCED THERMIONIC ENERGY CONVERTER”,
   from Stanford University and the Massachusetts Institute of Technology.
The “THERMO-PHOTOVOLTAIC DEVICE OF NEAR FIELD ENHANCED WITH TERMIONS”,
   developed by the Solar Energy Institute of the Polytechnic University of Madrid (UPM) in cooperation with the Center for Energy and Thermal Sciences of Lyon, among many others.

It is convenient to make a parenthesis, to highlight an interesting aspect in the operation of valves, or thermionic devices in general.

When the electrons detach from the cathode and travel even a tiny space to reach the anode, they dissipate “without direction” everywhere, as occurs with electrons in the photoelectric effect described in (FIG. 1); to avoid that and to be able to direct them, it is a common practice to conduct them with a magnetic field, or rather in most cases by intentionally polarizing the cathode and anode to force the electrons to cover the path that separates them, but for this they use additional electrical energy, foreign to the transducer itself.

### Thermoelectric Devices:

Seebeck, Peltier and Thomson effects.

Of these devices we only want to highlight (for the purposes of this document):
Of the Seebeck effect, relative to the absolute Seebeck coefficient “S_{ab}” of materials that could randomly form ordinary thermocouples.
From the Peltier effect, the union of the thermoelectric pairs of semiconductors “N” and “P” of the Peltier or commercial photovoltaic cells, and
From the Thomson effect, the fact that only thanks to its equations the Absolute Seebeck coefficients “S_{ab}” to which we are referring to can be determined.

As in the case of the work functions discussed earlier, when two materials (usually metals) are brought into contact, an interaction will occur that will now be between their respective Absolute Seebeck coefficients. Generally, one works with the “Seebeck Coefficient of Thermoelectric Couple” as one, because there is no experimental method to directly find the absolute Seebeck coefficient for an individual material. However, using Thomson's equations known as Kelvin relations, it has been possible to find the absolute Seebeck coefficient of a REFERENCE MATERIAL; then pairs of that reference material are formed with each of the materials whose absolute Seebeck coefficient is to be found, the Seebeck coefficient of each pair is measured, and with a mathematical compensation operation the absolute coefficients of the different elements are obtained.

Platinum (Pt) has been used as a reference material, and the values of the Absolute Seebeck coefficient (in mill volts/degrees Kelvin) of some materials are referred to in the following list:

TABLE 2¹

| | | |
|---|---|---|
| Selenium (Se) +895 mV/K | Tellurium(Te) +495 mV/K | Silicon (Si) +435 mV/K |
| Germanium (Ge) +325 mV/K | Antimony (Sb) +42 mV/K | Chromel (NiCr) +20 mV/K |
| Molybdenum (Mo) +5 mV/K | Cadmium(Cd) +2.5 mV/K | Tungsten (W) +2.5 mV/K |
| Gold (Au) +1.5 mV/K | Silver(Ag) +1.5 mV/K | Copper (Cu) +1.5 mV/K |
| Tantalum (Ta) −0.5 mV/K | Rhodium (Rh) −1 mV/K | Aluminum (Al) −1.5 mV/K |
| Carbon(C) −2 mV/K | Mercury(Hg) −4.4 mV/K | Chromium (Cr) −4.9 mV/K |
| PLATINUM (Pt) −5 mV/K | Sodium (Na) −7 mV/K | Potassium (K) −14 mV/K |
| Nickel (Ni) −20 mV/K | Constantan (NiCu) −40 mV/K | Bismuth (Bi) −77 mV/K |

¹https://es.qwe.wiki/wiki/Seebeck coefficient; https://doi.org/10.1002/pssb.2221810217

For this design we will use the absolute Seebeck coefficients of the metals that make up the “discharge or drain electrodes” of the transducer. These electrodes are those that are in direct contact with the cathode and the anode of the nucleus, which is the element of the device in which the thermoelectric conversion begins.

They are composed of segments of different metals chosen precisely by the relationship between their respective absolute Seebeck coefficients, and it is through them that the electric current flows to the terminals of the transducer.

Only thanks to the action of heat and the absolute value of their respective Seebeck coefficients, one of the two metals will be more or less positive or more or less negative than the other depending on the case; this will be the case even if the absolute Seebeck coefficients of the two interconnected metals are of the same sign, or are of opposite signs but of equal magnitude.

The heat of the core is transmitted by conduction through the various metal segments that make up the discharge or drain terminals, and generates or causes different thermal gradients to occur between its various junctions, because the metal segments have different levels of thermal conductivity as referred to in previous paragraphs, and because they are progressively further away from the core, which is the hottest point of the device, so the temperature will also decrease as the distance that separates them from the core increases.

In the proposed design, to structure the discharge or drainage electrodes, the most negative metal segments are intercalated with the most positive ones, and in this way a “cascade potential difference” is generated, which added to the temperature gradients that are created from the core itself (hottest point) to the last elements of the chain which are the transducer terminals (least hot point), induce more energy to the electrons so that they circulate with greater fluidity, preventing them from piling up at some point along their path, and avoiding the formation of the unwanted electron cloud that tends to form over the anode in thermionic transducers.

With some simple examples, we will try to demonstrate how the device takes advantage of this potential difference in “CASCADE”.

In FIG. 4: the two metals, Aluminum (1), with absolute Seebeck coefficient “S_{ab}”=−1.5 mV/K and Nickel (2), with “S_{ab}”=−20 mV/K, interconnected by a conductor (3) whose Seebeck coefficient is neutral for the system, whatever that conductor may be (according to the 2nd law of thermoelectric couples) which expresses: “In a thermoelectric circuit, composed of two different metals, there will be no alteration of the e.m.f. if we insert a generic metal at any point and keep the new joints at equal temperatures”. Although the two materials have negative Seebeck “S_{ab}” coefficients, it is easy to determine theoretically what the polarity of the pair will be; and in fact, in practice, what is expected happens, (1) is the positive element of the pair and (2) the negative element.

We then have that the polarity of this Seebeck pair is (+Al)---(−Ni)=>(+1) (−2).

Now let's see how the connection of a fourth metal can influence, which is attached to a working thermoelectric couple (third law of thermoelectric pairs) that says: “The e.m.f. produced in a thermoelectric circuit of two homogeneous and different metals, with their junctions at temperatures T1 and T3 respectively, is equal to the algebraic sum of the e.m.f. of this circuit with the junctions at temperatures T1 and T2 added to the e.m.f. of this same circuit with the junctions at temperatures T2 and T3”.

FIG. 5: if we suppose that the same pair “Al—Ni” is subjected to a temperature gradient in which the temperature t1 (5) of the junction [+1 (+3−)−2] (subjected to heat) is greater than the temperature t2 (6) at which its extremes “E1 (8) and E2 (9)” (room temperature) are found, of course still being the polarity of the pair (+1) and (−2).

With this configuration, the potential difference and the electric current are measured between E1 (8) and E2 (9), and we have:

Original torque (+Al)---(−Ni)=>(+1)---(−2)=12.6 mV; 12.6 μA.=>that the electrical resistance is R=1 KΩ.

Now we connect to this thermoelectric pair a fourth metal, NickelCromo; “NiCr” (4) with Sab=+20 mV/K, first at the E1 end (8), and we again take the intensity and voltage measurements and then we will do the same with the E2 end (9), both connections will be at the same temperature t2 (6) (ambient temperature).

But first, we will determine the polarity of the pairs that will be formed, and we can do it empirically and/or according to what table 2 indicates.

Combination of “NiCr” with “Al” to form a Seebeck thermoelectric pair=(+NiCr)---(−Al)=>(+4)---(−1);

Combination of “NiCr” with “Ni” to form another Seebeck thermoelectric pair (+NiCr)---(−Ni)=>(+4)---(−2).

In both combinations the “NiCr” is positive when forming the Seebeck pairs with the two metals separately.

This means that “NiCr” is: if not of opposite polarity, at least more positive than “AL” when combined with it (but we know from the table that indeed it is of opposite polarity to “Al”), =>“NiCr” S_{ab}>>“Al” S_{ab}; and that

“NiCr” when combined with “Ni” is of opposite polarity to this, =>“NiCr” S_{ab}>>“Ni” S_{ab}.

But in the original pair “Al—Ni”, “Al” is less negative than “Ni”, “Al” S_{ab}>“Ni” S_{ab}.

Doing the indicated we register:

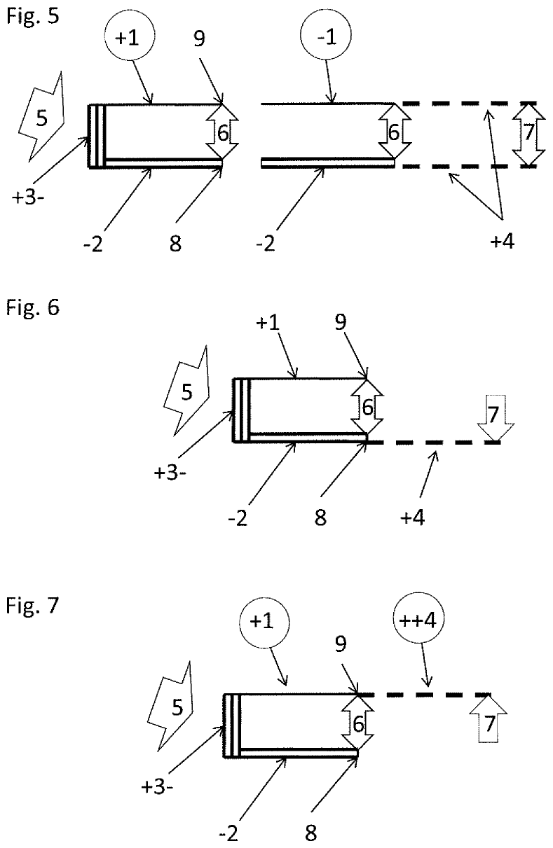

FIG. 6 (+Al)---(−[−Ni+NiCr])=>(+1)---(−2---+4)=11.7 mV;11.6 μA.=>R=1,0086206 kΩ.

FIG. 7 [+Al++NiCr]---(−Ni)=>(+1---++4)−(−2)=14.8 mV; 14.7 μA.=>R=1,006 802 7kΩ.

NOTE: For the e.m.f. in this example we take the Voltage with the open circuit and the current in a closed circuit with a resistance of one ohms (1Ω).

Although t2 (6) and t3 (7) are apparently the same temperature (room temperature), which is surely lower than the temperature of t1 (5); due to the conduction of heat that spreads through the materials used in the composition of the device (metals), t2 (6) in practice will be hotter than t3 (7); Therefore, a thermal gradient is created between these two points (6 and 7); thus the thermoelectric pairs of the discharge electrodes that are in the temperature gradient [between t1 (5) and t3 (7)], appropriately placed according to their specific “S_{ab}” coefficients, will generate an e.m.f. additional that will increase the final power of the device, as can be seen in the measurements made with the previous combinations, between the figures FIG. 5, FIG. 6 and FIG. 7.

Finally we have the PELTIER CELLS, which are based on the same principle of the Seebeck effect but in reverse. The passage of current is used through two different metals joined together by one of their ends, to cause an increase in temperature in the union and a reduction in temperature at the free ends.

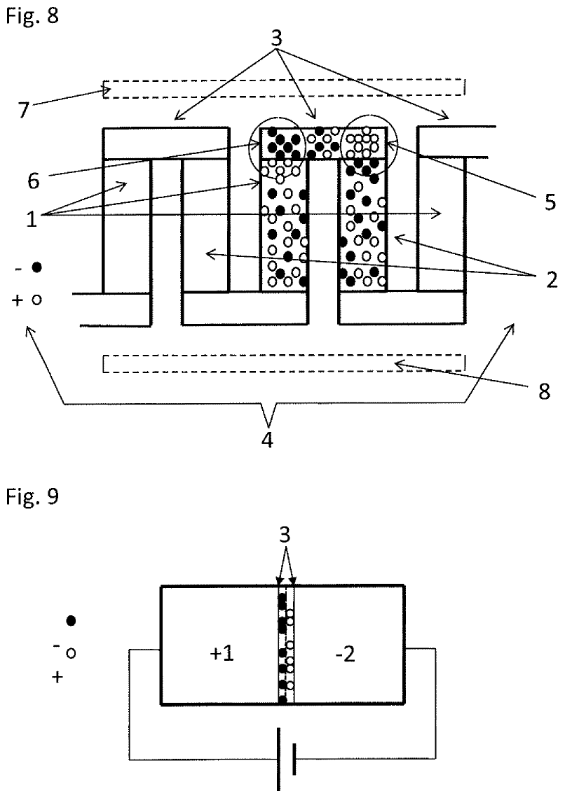

At present, instead of using metals, all Peltier cells are constituted by the union of semiconductors in pairs with a particular design, the electrical polarity of their elements is well defined as a product of the doping to which they have been subjected before forming the pairs; the constant is the junctions “N-P” of semiconductors FIG. 8.

It is interesting to note that in this case the semiconductors “N” (1) and “P” (2) are not in direct contact with each other as occurs in a photovoltaic cell, if not joined by a good electrical conductor (3) (usually metallic) so that the current can flow freely along the series of pairs of semiconductors (4).

Referring again to the 2nd law of thermoelectric pairs, it is understood that this electrical conductor (3) whether metallic or not, it does not intervene in the process, it is a passive element of the system and it only serves as a current conductor; on the other hand, as it is a union of a semiconductor with another material, which as said before is generally a metallic conductor (metal-semiconductor union), whose interaction we will see later in greater details; it is also necessary to highlight that although it is a chain of this type of junction (a large number of semiconductor pairs connected in series) (4), the electrical tensions that are generated by the interaction of ionic charges in the contact points of the metal with semiconductors, compensate each other, because in that case, those generated between the metal (3) and the semiconductor “P, −i.anions” (5), will be opposite to those generated at the other end of the same section of metal (3) in physical contact with the semiconductor “N, +i.cations” (6), as highlighted in the circles; so the junctions will be electrically neutral, and there will be no potential difference (pd) or voltage between the semiconductors “N” and “P” at any point in the chain of pairs, as long as there is no temperature difference between its two faces, hot (7) and cold (8).

So far we have presented some transducers and the thermoelectric effects that support their operation, and we have related them to the thermoelectric device proposed in this application.

Now we will refer to the characteristics that relate it to the electronic devices mentioned in the summary (diodes and transistors).

In the first place we refer to an electronic device called “DIODE”, which in general terms is a component that allows the current to flow through it in a single direction; specifically it is about the “Schottky diode” or Schottky barrier diode FIG. 9.

Consisting of a metal (+1)--semiconductor type “N” junction (−2), instead of the conventional junction of two semiconductors “N-P”.

The most common contact metal used for the construction of Schottky diodes is “silicide”; which is a compound of silicon and other electropositive elements (the most electropositive elements are the alkali metals); this is done strictly for functional reasons of the diode, with this it is achieved that the metal has a greater tendency to reject the electrons of the “N” doped semiconductor with which it forms the union, this reduces to a minimum the “depletion region or potential barrier” (3) in the Metal-semiconductor “N” junction, and allows the reaction of the Schottky diode to be much faster than that of ordinary diodes.

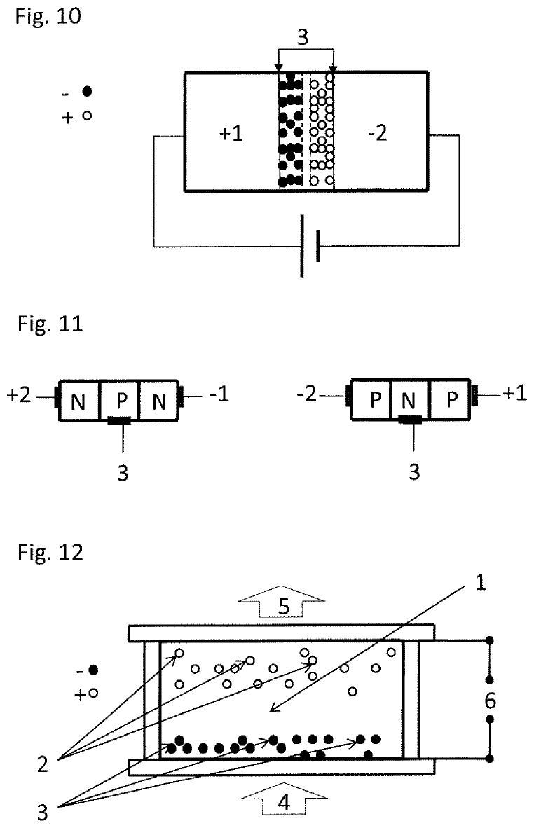

In FIG. 10, the union used in common diodes is shown, semiconductor “P” (+1)--semiconductor “N” (−2) which is the same grouping “P-N” of semiconductors that make up Peltier cells and photovoltaic cells, of course with a different design because their performances are also different; in this case it can be noted that the potential barrier (3) is very wide, because the electro negativity of the semiconductor “P” towards the electrons of the semiconductor “N” is also very high.

The detailed operation and use of the Schottky barrier diode are not relevant to this work; our specific interest is only to highlight the type of union between the materials that compose it.

Secondly we have the conventional solid state “TRANSISTOR”; Like the diode, it is an electronic element; but it is mainly used in a circuit as a switch, signal amplifier, oscillator or rectifier; It uses the fluctuation of a small electrical input signal at one of its terminals. FIG. 11.

This consists of three elements, each one is a conveniently doped semiconductor (they can be “NPN” or “PNP” according to their designation): the emitter “E” (+ or −1) that generates carriers, the collector “C” (+ or −2) that receives or collects them, and the third, the base “B” (3), is sandwiched between the first two, and regulates the passage of said carriers with a small electrical input signal.

It behaves like an on-off switch (cut and saturation):

When the base voltage is zero or less than 0.6 vl (this margin may vary with the manufacturer), the transistor fails to activate the passage of current between the collector and the emitter, and acts as an open switch (no current passes), on the other hand, when it reaches 0.6 vl, it begins to allow current to pass through (closes the circuit) and regulates it according to the value of that voltage.

hand, when it reaches 0.6 vl, it begins to allow current to pass through (closes the circuit) and regulates it according to the value of that voltage.

It behaves as an (active) amplifier:

When with the small base current it controls the greater current of the collector, achieving its amplification. The smaller current at the base acts as a “valve”, regulating the larger current from the collector to the emitter, but the transistor itself does not provide any additional power to the circuit.

In addition to these functions, which are what we are interested in highlighting for the purposes of this work; They can also be used as said before to fulfill other tasks, and for this there are different types of transistors, each one with particular characteristics; for example power, high frequencies, to amplify low-level signals and even special light-sensitive transistors such as phototransistors.

Until very recently, the statement made at the beginning (in the summary) was entirely true, “The energy source that activates electronic devices such as transistors and diodes is generally electrical”. But in 2017, the work developed by researchers from Linköping University in Sweden was published, in which they present “The first Heat Activated Transistor” FIG. 12, whose input signal is thermal and not electrical as in conventional transistors.

This new “transistor” consists of a polyethylene oxide electrolyte treated with NaOH (1) that has free ions (2) and conductive polymer molecules (3). Positively charged ions move very quickly, while polymers negatively charged due to their much larger size move much more slowly. When the assembly is subjected to a heat source (4), the ions “fly” to the cold side (5) farthest away, leaving the polymers behind; This separation creates a potential difference (6) which is what activates the transistor; with this operation it acts as an on-off switch, without providing additional energy to the circuit.

### Structure of the Thermoelectric Device Presented:

As said in the summary, it is a thermoelectric device that receives energy from an external heat source, and uses that energy to heat a cathode which in turn generates by radiation, a flow of electrons that will finally produce the electric current. It was also mentioned that its physical structure is similar to that of a Schottky barrier effect diode, with the difference that instead of being constituted by a metal-semiconductor union like these, it is formed by a union of a metal—with a basic oxide or metal oxide.

Metal oxides, also known as basic oxides, are inorganic compounds naturally formed by metal cations (M+) and the oxide anion (O2−) oxygen, between which there is an electrostatic interaction; where (M+) is any cation derived from a pure metal.

But the set of metallic oxides is very extensive, and with very varied characteristics; so that as possible components of the metal-metal oxide union that interests us, metal oxides that could interrupt the flow of current (insulators) are discarded, and only conductive metal oxides and electrical semiconductors will be considered, which by preference are:

Titanium oxide (TiO2), nickel oxide (NiO), tungsten oxide (WO3), chromium oxide (CrO2), chromium III oxide (Cr2O3), vanadium oxide (VO2), ruthenium oxide (RuO2), iron oxide III (Fe2O3), and copper oxides I and II (Cu2O), (CuO).

These basic oxides, in addition to containing the electrical charges (ions) necessary to establish a metal-metal oxide union, share certain characteristics among themselves, of which the most useful for this design are: their high ionic mobility, which allows them to perform well. as solid electrolytes; be good conductors of electricity under certain conditions; and also have high melting points.

Something similar happens when selecting the metals for that composition; There is a considerable number of them in the periodic table, so we will take into account only those that can compose a metal-metal oxide union with the characteristics we want (these characteristics will be detailed with the explanation).

These are among the so-called transition metals; The “IUPAC” (International Union of Pure and Applied Chemistry) defines a transition metal as “an element whose atom has an incomplete sublayer (d) or which can give rise to cations with an incomplete sublayer (d)”. According to that definition the transition metals are the forty chemical elements of the “d” block of the periodic table, subtracting the Zinc, Cadmium and Mercury that have the complete subshell (d) (10 electrons).

But in addition to this condition, there are others that reduce a bit the set of selectable metals that which are: for safety reasons, they should not be radioactive or toxic in nature; and for practical reasons, they cannot be “synthesized” metals, because these are not common and are only used for scientific research purposes.

This leaves us with a total of twenty-one (21) metals (table 1.) which can be used to make a reasonable number of combinations with the aforementioned metallic oxides, and form the most convenient metal-metal oxide unions according to the specific use you want to give them.

The union between these groups of metal oxides and transition metals occurs because the former have electrically charged particles (ions) both positive (+ic. Cations) and negative (−ia. Anions) with high ionic mobility as mentioned before, while these specific metals use a particular mechanism to maintain their stability, called “Electronic Transition”, which consists of completing the electrons that are missing in their last valence shell, extracting them from other internal layers that in turn remain incomplete, but they are compensated by doing the same with the electrons of other inner shells and so on. (Every time an electron moves, it leaves a hole that can be filled by an electron that could come from another material).

Exactly in that line of physical contact, an ion exchange occurs between the two materials, which is verified by the presence of a potential difference (p.d.) at their ends, with a polarity opposite to that of the device when it is active. This area occupied by the ions (cations and anions) constitutes a depletion region or internal potential barrier, as it occurs in the union of common diodes, conventional transistors and Schottky diodes, but in this case it is made of materials without any doping, and it is also a “non-ohmic junction” which means that, if the device is not in operation, the passage of current is restricted in both directions of the union, that is that it has no electrical continuity in either direction. From this moment, these two elements become the cathode and the anode that make up the “CORE” of the proposed thermoelectric device.

At this point it is important to note that, with the devices in the “off” position (which are not operating); the bonds between the active components of any thermocouple or Peltier cell; they allow the passage of current in both directions, that is, they have electrical continuity between their ends in both directions. But the same does not happen with a diode valve or a triode, that if they are not operating, it is not possible for the current to flow between their cathode and anode in any sense, that is, electrical continuity is not possible under those conditions. However, for both diodes and transistors, there is always one sense in which current can flow with some freedom, and another sense in which the resistance is so high as to restrict the flow of current.

The electrical resistance of the core of the device that is presented is directly proportional to the thickness of the metal oxide substrate deposited on the metal and dependent on the oxide and the metal that compose it (according to the combinations). For the same given composition (metal-metal oxide) of the core, if the resistance is increased, the depletion region or potential barrier between the two materials of the core will also increase proportionally; so that, depending on the use to which the device is intended, the resistance can be made so high as to interrupt current flow through the core until it reaches very high temperature levels, or it can be minimized by making the device so sensitive as to activate at much more moderate temperatures, simply adjusting the mentioned parameters in a convenient way.

Whatever the initial value of this resistance is, it will return to the same level once the external action that causes its variation ceases.

The ordinary diodes, conventional transistors (NPN or PNP) and Schottky diodes (metal-semiconductor), to overcome the potential barrier or depletion region at the junction between their components, which keeps the electrical circuit open (below the starting tension or threshold tension); they make use of the increase in the difference of potential or voltage between its extremes, which is supplied by an external current source; the former do it approximately at 0.6 Vol. and the Schottky at 0.2 Vol., these values are their respective starting tensions.

In the case of the device that we are presenting, regardless of the initial magnitude of the core resistance; by increasing the temperature of its structure either by direct contact or by thermal radiation from an external heat source, the initial magnitude of the resistance will be progressively reduced as if it were a THERMISTOR, which is: “A type of resistance whose value varies depending on the temperature, (Negative Temperature Coefficient or NTC), their resistance decreases as the temperature increases. (Positive Temperature Coefficient or PTC), increase their resistance as the temperature increases”.

And when the resistance reaches the minimum value predetermined by the selection of the core components and their dimensions, the internal potential barrier will be overcome, the circuit closes and allows the current to begin to flow through it; as happens with a diode or a transistor when they reach the starting voltage; But in the case of this device, the resistance will be adjusted not only to the voltage of the external source that feeds the circuit, which is inevitable by Ohm's law, but also to the temperature of the environment.

As this is also a “thermoelectric transducer”, at the same time that the increase in temperature progressively reduces the electrical resistance in the core and consequently overcomes the potential barrier; the cathode of the same will begin to release electrons and will also progressively increase its emission, so that the two effects are produced at the same time that, by the aforementioned Ohm's law, can be used to make the current pass through any be the type of union between two materials (reduction of electrical resistance in the union or increase in voltage between its ends).

On the other hand, the loss of energy that occurs through radiation, as a result of the conduction of heat along the solid structure of the device, is partly compensated by the e.m.f. generated by the Seebeck effect between the contact points of the metals that make up the “discharge or drain electrodes”, so that something similar to what was detailed in the example with FIG. 5, FIG. 6 and FIG. 7, because they have different thermal gradients “Table 1”, different absolute Seebeck coefficients “Table 2”, and are linked by alternating their respective relative polarities.

It is important to emphasize that the metal to be used does not necessarily have to form a union with its own metallic oxide, as we have done now in order to facilitate the work; each combination of metal-metal oxide can be random, and its selection will depend on which are the operational characteristics that can be obtained with each specific combination; however, to place an oxide layer on any metal it will be necessary to use more complex deposition methods than the simple thermal oxidation used in this case.

### Transducer Operation:

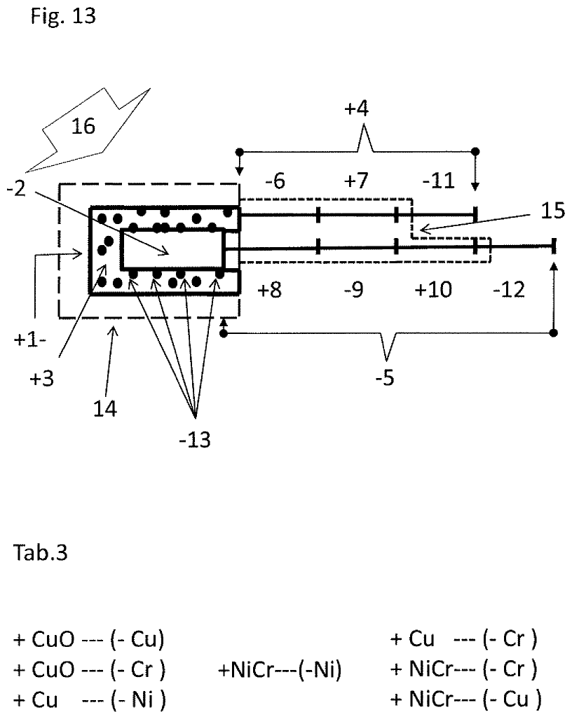

The FIG. 13 shows in detail the design of the device, with the relative polarities of its components; and in the attached table, Table 3, the polarities that are obtained in practice are shown when these metals are joined together (their respective coefficients “S_{ab},” are those of Table 2).

The design comprises: A “solid state nucleus” (+1−) constituted by the union of a metal “Cu” (−2) which in this case is the anode, covered by a basic or metallic oxide “CuO” (+3) what is the cathode; These are in turn connected, each one to a discharge or drain electrode “+ed” (+4) and “−ed” (−5) formed by a chain of metallic conductors “Cr” (−6), “Cu” (+7), “NiCr” (+8), “Cr” (−9), “Cu” (+10), (the polarity of each of these segments is only relative to the polarity of the preceding and the successively according to their respective absolute Seebeck coefficients), and which are finally joined to the transducer terminals “+t Ni” (−11) and “−t Ni” (−12).

The core of the device (+1−), with its components (−2) and (+3), is covered by a dark protective resin resistant to high temperatures (14), and the drain or discharge electrodes are normally exposed, but if the outside temperature were very high, they could be covered with a heat sink (15) as is done with any other electronic component.

When the nucleus (+1−) receives radiation from the heat source (16), from the cathode (+3), a flow of electrons (−13) is generated as occurs in any thermionic transducer; but here the electrons are not detached from the cathode (+3) to move through a vacuum and reach the anode (−2), but rather they stay near the cathode surface, and due to the potential difference generated by the interaction between the work functions of the two components of the nucleus, are immediately trapped by the anode as occurs in photovoltaic cells; as these electrons are not given energy to move (kinetic energy), the device requires less temperature to operate compared to a common thermionic device, although since it is thermal radiation, its operating temperature will undoubtedly be higher than that of a photovoltaic transducer.

In detail by sections it works as follows:

The elements of the nucleus are physically united, although separated electronically by the ionic potential barrier, the two are at the same temperature, but only the one with the lowest work function will begin to emit electrons (it becomes the cathode), before the other (which instantly becomes the anode); this effect defines the potential difference in the nucleus, and directs the movement of the electrons.

The metals that make up the discharge or drainage electrodes (+4) and (−5), are joined by inserting their relative polarities (−6/+7/−11) by the “+ed” (+4); and (+8/−9/+10/−12) by the “−ed” (−5), which generates a potential difference (p.d.) in cascade between all the metallic segments, from the nucleus (+1−) up to the terminals “+t Ni” (−11) and “−t Ni” (−12); Furthermore, their different values of thermal conductivity and the progressive increase in the distance that separates them from the hottest point of the device (the core), create a descending chain of thermal gradients to the least hot point (terminals −11 and −12); all together, it prints more energy to the flow of electrons coming from the nucleus, due to the potential difference, and generates art electromotive force (by Seebeck effect) that adds to the current of the nucleus, and facilitates the path of the electrons avoiding that agglomerate at some point in the structure, thus avoiding the unwanted formation of the electronic cloud on the anode of the device.

As we can see, the entire process described occurs without the presence of an extra source of electrical energy, the only energy used by the device is thermal energy.

In such a way that, if they are conveniently joined with the appropriate connections in series and in parallel, as many units of this device as deemed convenient, a thermoelectric cell can be composed with the desired power to form thermopiles and generators as is done with other devices similar, only in this case it would not be thermionic or photovoltaic, because although its energy source is thermal like a thermionic transducer, it processes that energy as a photovoltaic cell does. A very generic qualifier could be “thermoelectric transducer”, or more specific “thermo voltaic transducer”.

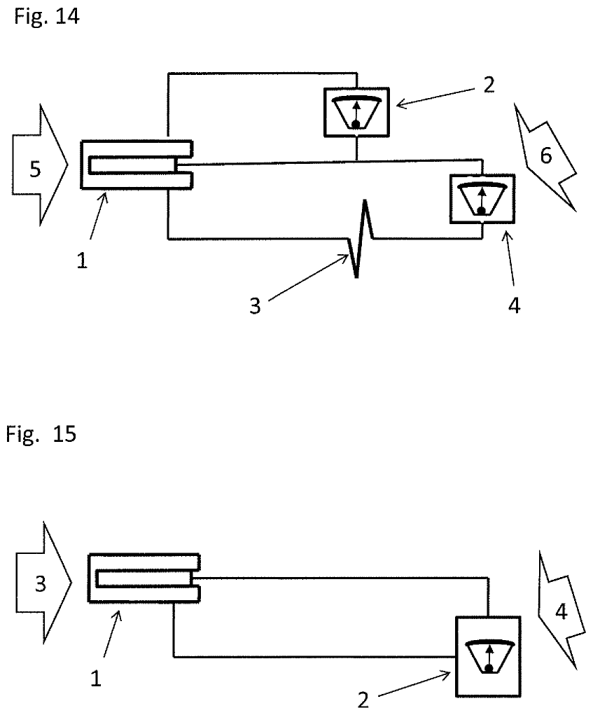

In FIG. 14 the behavior of the device is checked in unit: The core of the thermoelectric device (1), is connected in series to the voltmeter (2), and at the same time in series with a resistance of Re=1.3Ω (3) and the ammeter (4), the core is at a temperature t1 (5) and its electrodes, terminals and the meters separated from it, at a temperature t2 (6).

When the temperature is the same throughout the circuit t1=t2, the voltage measured by the voltmeter with the circuit open is V=−5.00 mvl. (The negative voltage is due to the existence of the depletion region or internal potential barrier with reverse polarity mentioned above).

When the circuit is closed with the resistor (3) and the ammeter (4), the voltage on the voltmeter is V=0.0 Vol. And the current measured by the ammeter is I=0.0 A.

When the temperature t1 (5) increases in the core and t2 (6) is maintained at room temperature t1>t2, a potential difference and an electric current are produced in the circuit that increase with the thermal gradient between the two temperatures. In this case they reach V=193 mvl. and I=189 μA., this indicates that the device works effectively as a thermoelectric transducer; and as outlined before, it confirms the possibility that, as in the case of any other type of thermoelectric transducer, by suitably grouping a certain number of these elements, a thermopile can be composed.

### Second Form of Employment:

But this device can also be used independently, because it has certain operational characteristics that could be useful in an electrical or electronic circuit, which are specifically the following:
It acts as an on-off switch (commutation) with the variation of external temperature.
Works as an NTC Thermistor.
So as it progressively reduces the electrical resistance between its terminals with increasing temperature, it also gradually increases the power (voltage and current) in the circuit.

That is, if the device is used as an isolated element by inserting it into a circuit, it works as an on-off THERMO-ELECTRIC SWITCH and NTC THERMISTOR. (negative temperature coefficient) with increase in ELECTRICAL POWER; or cataloging it in an even more generic way, it resembles a SOLID STATE THERMAL TRANSISTOR (solid dielectric) WITH INCREASED ELECTRIC POWER.

The following figures show a single element of this device, connected in four simple circuits, also performing in four different ways as an electronic regulator axed by heat:

The FIG. 15: Shows the thermoelectric device (1) connected in series to an Ohmmeter (2). The core of the device is at a temperature t1 (3), and its electrodes, terminals and the meter are separated from it, at a temperature t2 (4).

When the temperature is the same throughout the circuit t1=t2, the Ohmmeter (2) marks a certain internal resistance characteristic of the combination of the materials that make up the core and the temperature of the environment, which at this moment is (t1=t2). In this case Ri is > at 1,723 MΩ.

Keeping t2 (4) at room temperature and increasing t1 (3) progressively t1>>t2, the electrical resistance is also progressively reduced, taking lower and lower values.

Although this does not happen in practice, in theory it is said that it tends to zero (Ri→0). The device is working as an NTC THERMISTOR.

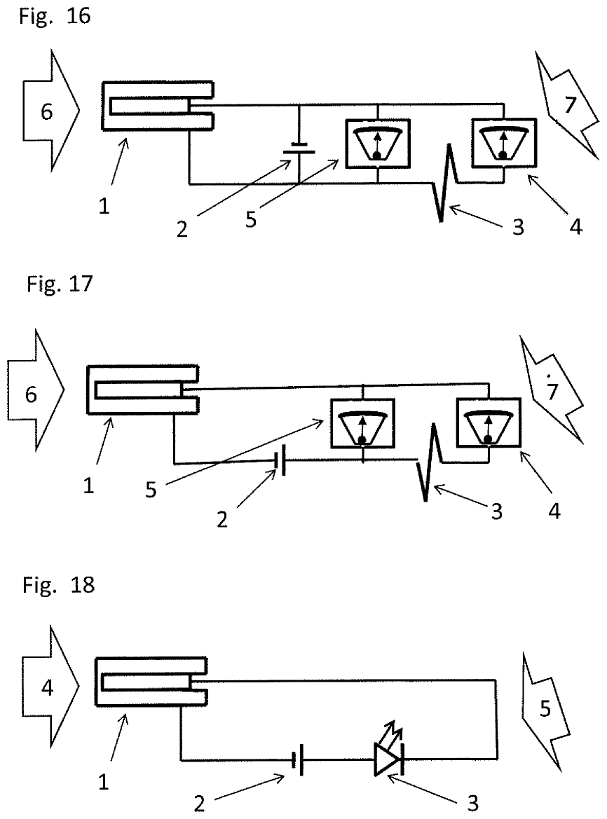

FIG. 16: Shows the thermoelectric device (1), connected in parallel with a DC. source. of V=1,380 Vol. (2); both are connected in series with an external resistance of Re=998Ω (3), and with an ammeter (4). In parallel with the circuit (2), (3), (4) a voltmeter (5) is connected. The core of the device is at a temperature t1 (6), and its electrodes and terminals, the meters (4), (5), the source d.c. (2) and resistance (3) separated from it, at a temperature t2 (7).

When the temperature is the same throughout the circuit t1=t2, the voltage and the current flowing through the circuit measured independently, one first, and then the other are respectively:

V₁=1,380 Vol. And I₁=1,238 mA.

And measured at the same time are: V₂=1,357 Vol. And I₂=1,236 mA.

It is as if the device does not exist. The difference between V₁, I₁ and V₂, I₂ is only by the presence of Re.

When the temperature t1 (6) increases in the core, and t2 (7) is kept at room temperature t1>t2; As the thermal gradient between t1 and t2 increases, a progressive reduction in both the potential difference and the electric current occurs in the circuit, as low as: V₃=0.371 Vol. and I₃=0.328 mA.; much lower than the DC. source (2) alone.

In this case the device behaves like a DC. source. with a very low voltage, connected in parallel to another DC. source. with a much higher voltage, as expected, (parallel connection of two batteries with different voltages).

FIG. 17: Shows the thermoelectric device (1), connected in series with a DC source. of V₀=1,401 Vol. (2), an external resistance of Re=1.3Ω (3), and with an ammeter (4). Between the negative of the core (1) and the positive of the source (2) a voltmeter (5) is connected. The core of the device is at a temperature t1 (6), and its electrodes, terminals and meters separated from it, at a temperature t2 (7).

When the temperature is the same throughout the circuit t1=t2, the voltage and current flowing through the circuit measured independently of each other are respectively:

V₁=1,115 Vol. and I₁=0.013 mA.

When the temperature t1 (6) increases in the core and t2 (7) is kept at room temperature t1>t2, a potential difference and an electric current are produced in the circuit that increase with the thermal gradient between the two temperatures. In this case:

V₂=1,485 Vol. and I₂=19.6 mA.

The increase in voltage and current taken initially with the open circuit is clearly appreciated

V₀=1,401 Vol.

V₁=1,115 Vol. and I₁=0.013 mA.

V₂=1,485 Vol. and I₂=19.6 mA.

This means that the device is adding power to the DC source in the circuit, and increases its POWER. Which agrees with the performance of the device described in FIG. 14.

FIG. 18: Shows the thermoelectric device (1), connected in series with a DC. source. of V=1.78 Vol. (2), and an LED (3). The core of the device is at a temperature t1 (4), while separated from it, the rest of the circuit components are at a temperature t2 (5).

When the temperature is the same throughout the circuit t1=t2, the voltage and current flowing through the circuit are respectively: (with the voltmeter on the 20 Vol. Scale) at the terminals of the LED. V=1.63 Vol. (This red led lights up at 1.9 Vol.); at the core terminals V=0.91 Vol.; (with the ammeter on the 200 mA scale.) in the circuit the current is I=0.00 A. So the LED. It remains off.

When the temperature t1 (4) increases in the core and t2 (5) is kept at room temperature t1>t2, the current in the circuit increases progressively with the temperature until I=10.9 mA. and the voltage on the LED terminals reaches V=2.04 Vol. causing it to turn on.

In this case the device works as an on-off current switch.

Making a general summary of the characteristics of the device presented in this application, and comparing it with its similar operative ones, and even with the designs that are in their final development phase, we can conclude that:

Although its power is modest, only about 40 μW. single core; The size of the device and the number of units can be varied, to compose a thermoelectric battery or a generator of several cells according to the desired capacity, the same has always been done with thermionic generators, but taking advantage of the operating characteristics typical of this particular design.

The potential difference between the cathode and the anode is generated spontaneously, without having to polarize them using an additional current source, or having to subject the device to the action of an external magnetic field to direct the electrons towards the anode.

All the heat that in other similar devices would be lost by conduction or radiation after having induced the radiation of the electrons, this device takes advantage of it to a large extent by causing repeated thermal gradients between the sections of the discharge electrodes, which generate a small amount of energy (e.m.f.) to be used by the same dev ice.

The formation of the electron cloud that tends to accumulate on the anode of thermionic devices is avoided in a relatively simple way, and that in other designs, it is a matter of reducing or eliminating with much more elaborate procedures and devices, using not only energy electricity from additional sources, but also very special materials and structures such as nanometric components.

Unlike other similar devices, it does not require that there is a temperature difference (thermal gradient) between the cathode and the anode. As long as there is sufficient energy, the cathode will emit the electrons, because its working function or extraction energy will still be lower than that of the anode within the temperature range in which the device can operate.

In short, it is a simple device to manufacture, inexpensive, it is produced with very common materials that do not require high purity such as semiconductors, or previous treatments such as doping, and with production techniques available to any modest laboratory. After its useful life it can be 100% recycled, and if it is not, it decomposes in the environment with the same risks of contamination from any other metal; It is a solid state device, and due to its very composition, it has good mechanical and thermal resistance; and in addition to being able to be used together as to make a battery or a thermoelectric generator, it could be used individually as a “regulator or thermoelectric transistor with power increase” in an electronic circuit.

1- Transducer and thermoelectric transfer resistor, characterized by receiving heat from an external source (input) and converting it by thermal radiation into a flow of electrons that in turn generate electrical energy (output).

2- Transducer and thermoelectric transfer resistor according to the preceding claim, which is characterized by being formed by the physical union of a transition metal with a metallic oxide or basic oxide, both without any doping, which function indistinctly as cathode and anode, and constitute the nucleus of the thermoelectric device.

3- Transducer and thermoelectric transfer resistor, which according to the previous claim, is characterized in that in said union an electric field is formed by the exchange of positive and negative ions between the two solid materials that make up the core of the device.

4- Transducer and thermoelectric transfer resistor, according to claim 2, characterized in that around said union, the depletion region or potential internal barrier is generated which create the electronic separation between the cathode and the anode of the device core.

5- Transducer and thermoelectric transfer resistor according to claims 2, 3, and 4, characterized in that said internal potential barrier is a “non-ohmic” junction between the cathode and the anode regulated by certain specific parameters, which restricts continuity between the components of the nucleus both in one sense and in the opposite sense.

6- Transducer and thermoelectric transfer resistor according to the previous claim, characterized in that the combination of the materials that form the core, and the thickness of the metal oxide that makes up the union; will determine the height of the device's internal potential barrier.

7- Transducer and thermoelectric transfer resistor according to claim 5, characterized in that only when the external temperature reaches the level established by the specific parameters of the design, the height of the device's internal potential barrier could be exceeded, and will start the flow of electrons between the cathode and the anode (particle radiation), causing the core of the device to start generating an e.m.f. towards the discharge electrodes.

8- Transducer and thermoelectric transfer resistor according to claim 2, which is characterized in that the cathode and anode of the device core are automatically polarized by themselves, due to the difference in the value of the work functions, between said cathode and said anode.

9- Transducer and thermoelectric transfer resistor according to the previous claim, characterized in that the cathode of the device will automatically be the component of the core whose working function is the least between the two.

10- Transducer and thermoelectric transfer resistor according to claim 8, characterized in that the anode of the device will automatically be the component of the core whose working function is the greatest between the two.

11- Transducer and thermoelectric transfer resistor according to claim 2, characterized in that the transition metal component of the core of the device can be one or all of the transition metals, which is not synthesized, toxic or radioactive, and whose atom has a sub layer (d) incomplete or capable of giving rise to cations with an incomplete sub layer (d)″.

12- Transducer and thermoelectric transfer resistor according to claim 2, characterized in that the basic oxide or metallic oxide component of the core of the device, can be one or all of the basic or metallic oxides that are conductive or electric semiconductors.

13- Transducer and thermoelectric transfer resistor according to claim 7, characterized in that within the operating parameters of the device, the cathode generates electrons and the anode receives the electrons, although said cathode and said anode are at the same temperature, because the relationship between their respective job functions does not vary with temperature.

14- Transducer and thermoelectric transfer resistor in relation to claim 2, characterized in that the cathode and the nucleus anode are independently connected to a discharge or drain electrode, each one of said discharge or drain electrodes composed of segments of various metals joined in series.

15- Transducer and thermoelectric transfer resistor according to the previous claim, characterized in that each of the metal segments placed in series, which make up the discharge or drain electrodes, has a relative polarity according to its own absolute Seebeck coefficient, and each segment is positioned so that it lies between two metallic segments with relative polarities opposite to that of said segment, to create a cascading potential difference with alternating polarities from the core to the terminals of the device.

16- Transducer and thermoelectric transfer resistor according to the previous claim, which is characterized in that this cascade potential difference progressively increases the kinetic energy of the movement of the electrons from the cathode, causing them to move more fluidly through the discharge electrodes, preventing them from piling up at some point along the way, which also prevents the formation of the “electron cloud” on the device's anode.

17- Transducer and thermoelectric transfer resistor according to claim 14, characterized in that each metal segment of the series is connected to another consecutive segment by a junction point, where said junction point is at a lower temperature than the junction point with the previous segment, but said junction point is at a higher temperature than the junction point with the consecutive segment, forming a descending chain of thermal gradients from the hottest core to the least hot terminals of the device.

18- Transducer and thermoelectric transfer resistance according to previous claim, characterized in that the chain of segments of different metals, combined with their different thermal gradients, also generate, due to the Seebeck effect, a sequence of electromotive forces from pairs of thermoelectric metals) that are added all, according to the third law of thermoelectric pairs (Law of accumulation of thermoelectric voltage, or Law of successive or intermediate temperatures). Therefore, the discharge or drain electrodes generate by Seebeck effect, an electromotive force independent of the electromotive force generated by the core of the device.

19- Transducer and thermoelectric transfer resistor according to claims 7 and 18, characterized in that the e.m.f. produced in the core (by radiation), adds to the e.m.f. generated in the discharge or drain electrodes (by Seebeck effect) that join said core with the terminals.

20- Transducer and thermoelectric transfer resistor according to claims 2 and 14, characterized in that the core of the device is covered by a synthetic resin for protection resistant to high temperatures of dark color, and the drain or discharge electrodes are placed on a standard heat sink for electronic circuits.

21- Transducer and thermoelectric transfer resistor according to the preceding claims, characterized in that it does not require additional energy from an external source, to polarize the cathode and the anode of the device or to direct the electrons emitted by said cathode.

22- Transducer and thermoelectric transfer resistor according to the previous claims, characterized in that the e.m.f. between the terminals of the device increases as the temperature of said device increases.

23- Transducer and thermoelectric transfer resistor according to the preceding claims, characterized in that the internal resistance of the device decreases as the temperature of said device increases.
